(19) United States
(12) Patent Application Publication
(10) Pub. No.: US 2005/0120962 A1
(43) Pub. Date: Jun. 9, 2005

(54) Substrate supporting table, method for producing same, and processing system

(76) Inventors: Joichi Ushioda, Nirasaki-Shi (JP); Koichi Sato, Hsin-Chu City (TW); Tsutomu Satoyoshi, Nirasaki-Shi (JP); Hiromichi Ito, Nirasaki-Shi (JP)

Correspondence Address: SMITH, GAMBRELL & RUSSELL, LLP, 1850 M STREET, N.W., SUITE 800, WASHINGTON, DC, 20036, US

(21) Appl. No.: 11/032,138

(22) Filed: Jan. 11, 2005

Related U.S. Application Data
(62) Division of application No. 10/067,506, filed on Feb. 7, 2002.

(30) Foreign Application Priority Data
Feb. 8, 2001 (JP) 2001-032712
Dec. 26, 2001 (JP) 2001-393918

(51) Int. Cl. C23C 16/00

(52) U.S. Cl. 118/728

(57) ABSTRACT

A plasma processing system has a susceptor, provided in a processing vessel, for supporting thereon a substrate. A process gas is supplied into the processing vessel to produce the plasma of the process gas. The susceptor has a dielectric film formed on a base, and a plurality of protrusions formed on the film. The protrusions of the susceptor are formed by thermal-spraying a ceramic onto the dielectric film via an aperture plate having a plurality of circular apertures.

### BACKGROUND OF THE INVENTION

1. Technical Field

The present invention relates generally to a substrate supporting table for supporting thereon a substrate, such as a glass substrate for a liquid crystal display (LCD), a method for producing the same, and a processing system for carrying out a process, such as dry etching with respect to the substrate by using the substrate supporting table.

2. Background Art

For example, in LCD manufacturing processes, plasma processing, such as dry etching, sputtering and CVD (Chemical Vapor Deposition), is widely used for processing an LCD substrate of a glass as a substrate to be processed.

In such plasma processing, for example, a pair of parallel plate electrodes (top and bottom electrodes) are arranged in a processing vessel, and a substrate to be processed is supported on a susceptor (supporting table) serving as the bottom electrode. Then, a process gas is fed into the processing vessel, and high-frequency waves are applied to at least one of the electrodes to form a high-frequency field between the electrodes. The plasma of the process gas is formed by this high-frequency field to plasma-process the substrate to be processed. At this time, the substrate has face-to-face contact with the top surface of the susceptor.

However, in fact, the surface of the susceptor is a slow curved surface, so that a very small gap is partially formed between the substrate and the susceptor. On the other hand, deposits accumulate on the susceptor by repeating the plasma processing.

As shown in FIG. 8, the deposits 47 accumulate so as to be filled in the gap between the substrate G to be processed and the susceptor 50. For that reason, there are portions in which the susceptor 50 directly contacts the bottom surface of the substrate G and portions in which the susceptor 50 contacts the bottom surface of the substrate G via the deposits 47. Due to the differences in thermal conductivity and electric conductivity between the directly contacting portions and the indirectly contacting portion via the deposits 47, there are some cases where etching irregularity exists on the substrate G (high etching rate portions and low etching rate portions exist on the substrate G. There are also some cases where the substrate G is stuck onto the susceptor 50 due to the presence of such deposits 47.

For that reason, for example, in a plasma processing system disclosed in Japanese Patent Laid-Open No. 59-172237, a plurality of conical protruding portions are provided on the top face of a susceptor (sample stage). However, in this system, the protruding portions are integrally formed with the susceptor. It is technically difficult to uniformly prepare such protruding portions by the machining of a metal, and it takes costs and a lot of time to do so.

In an electrostatic chuck and a method for producing the same disclosed in Japanese Patent Laid-Open No. 60-261377, a protruding pattern is formed on the surface of a burned ceramic insulating layer for covering an electrostatic electrode.

In a susceptor with pattern for reducing electrostatic force disclosed in Japanese Patent Laid-Open No. 8-70034, convex-concave patterns are formed on the top face of a susceptor by the photo-etching. Thus, electrostatic force (fixing force) can be reduced to easily separate a wafer from the susceptor after plasma etching.

In a susceptor for plasma CVD system and a method for producing the same disclosed in Japanese Patent Laid-Open No. 10-340896, the top face of a susceptor of aluminum or an aluminum alloy is shot-blasted to form convex-concave portions. By the chemical polishing, electrolytic polishing or buffing, the steep protruding portions of the formed protrusions are removed.

However, in these examples, there is a disadvantage in that dust produced by the plasma processing is easily deposited since the top faces of the protrusions are flat.

### SUMMARY OF THE INVENTION

It is therefore an object of the present invention to provide a substrate supporting table capable of eliminating the above described problems while preventing the disadvantages in that processing irregularities, such as etching irregularity, are caused by the accumulation of the deposits on a substrate supporting table and that a substrate is stuck onto the substrate supporting table, a method for producing the supporting table, and a processing system using the same supporting table.

In order to accomplish the above described problems, according to a first aspect of the present invention, there is provided a method for producing a substrate supporting table, the method comprising the steps of: forming a dielectric film on a base; and forming a plurality of protrusions of ceramic on the dielectric film by thermal-spraying the ceramic onto the dielectric film via an aperture plate having a plurality of apertures.

According to the same aspect, there is also provided a method for producing a substrate supporting table, the method comprising the steps of: forming a first dielectric film on a base; forming a conductive layer on the first dielectric film; forming a second dielectric film on the conductive layer; and forming a plurality of protrusions of ceramic on the second dielectric film by thermal-spraying the ceramic onto the second dielectric film via an aperture plate having a plurality of apertures.

According to a second aspect of the present invention, there is provided a substrate supporting table comprising: a base; a dielectric film formed on the base; and a plurality of protrusions of ceramic formed on the dielectric film by thermal-spraying.

According to the same aspect, there is also provided a substrate supporting table comprising: a base; a first dielectri@c film formed on the base; a conductive layer formed on the first dielectric film; a second dielectric film formed on the conductive layer; and a plurality of protrusions of ceramic formed on the second dielectric film by thermal-spraying.

According to a third aspect of the present invention, there is provided a processing system comprising: a processing vessel for housing therein a substrate; a substrate supporting table, provided in the processing vessel, for supporting thereon the substrate; gas supply means for supplying a process gas into the processing vessel; and exhaust means for exhausting gas from the processing vessel, wherein the substrate supporting table has a base, a dielectric film formed on the base, and a plurality of protrusions of ceramic formed on the dielectric film by thermal-spraying.

According to the same aspect, there is also provided a processing system comprising: a processing vessel for housing therein a substrate; a substrate supporting table, provided in the processing vessel, for supporting thereon the substrate; gas supply means for supplying a process gas into the processing vessel; and exhaust means for exhausting gas from the processing vessel, wherein the substrate supporting table has a base, a first dielectric film formed on the base, a conductive layer formed on the first dielectric film, a second dielectric film formed on the conductive layer, and a plurality of protrusions of ceramic formed on the second dielectric film, by thermal-spraying.

In the above cases, the protrusions are formed on the dielectric film by thermal-spraying the ceramic, so that the protrusions of the ceramic can be easily and uniformly distributed. These protrusions serve as spacers, so that it is difficult for deposits to contact a substrate to be processed even if the deposits accumulate on the substrate supporting table. Therefore, it is possible to prevent the disadvantages in that portions contacting the substrate supporting table via the deposits are formed in the bottom surface of the substrate to cause etching irregularity and that the substrate is stuck onto the substrate supporting table. It is easy to produce such a substrate supporting table.

In this case, if the above described base or conductive layer functions as an electrostatic electrode, it is possible to obtain a substrate supporting table having an electrostatic chuck.

According to a fourth aspect of the present invention, there is provided a processing system comprising: a processing vessel for housing therein a substrate; a substrate supporting table, provided in the processing vessel, for supporting thereon the substrate; gas supply means for supplying a process gas into the processing vessel; and exhaust means for exhausting gas from the processing vessel, wherein the substrate supporting table has a rectangular base, and a plurality of protrusions formed on the base, and the protrusions are arranged so as to form an orthogonal lattice on the base, an angle between one axis of the orthogonal lattice and one side of the base being from more than 0° to not more than 45°.

According to the same aspect, there is also provided a processing system comprising: a processing vessel for housing therein a substrate; a substrate supporting table, provided in the processing vessel, for supporting thereon the substrate; gas supply means for supplying a process gas into the processing vessel; and exhaust means for exhausting gas from the processing vessel, wherein the substrate supporting table has a rectangular base, and a plurality of protrusions formed on the base in an irregular arrangement.

According to these processing systems, it is possible to prevent a circuit pattern formed on the substrate from overlapping with the arrangement pattern of the protrusions, so that it is possible to avoid processing irregularities, such as etching irregularity.

In any one of the above described constructions, the protrusions preferably point-contact the substrate on the top faces thereof. Thus, it is possible to decrease the bad influence of the deposits. The top faces of the protrusions preferably consist of curved surfaces. Thus, angular portions (sharp-pointed portions) do not exist on the protrusions, so that the protrusions are not scraped off to cause particles.

### BRIEF DESCRIPTION OF THE DRAWINGS

FIG. 1 is a sectional view showing a plasma etching system as an example of a preferred embodiment of a processing system including a susceptor (substrate supporting table) according to the present invention;

FIG. 2 is a sectional view for explaining a method for forming protrusions of a susceptor in the system of FIG. 1;

FIG. 3 is a sectional view showing a state that deposits adhere to the susceptor according to the present invention;

FIG. 4. is a sectional view showing a susceptor in another preferred embodiment in which an electrostatic chuck is provided;

FIG. 5A is a sectional view showing a susceptor in another preferred embodiment according to the present invention;

FIG. 5B is a partial plan view of the susceptor shown in FIG. 5A;

FIG. 6A is a sectional view showing a susceptor in a further preferred embodiment;

FIG. 6B is a partial plan view of the susceptor shown in FIG. 6A;

FIG. 7 is a plan view showing a susceptor in a still further preferred embodiment; and

FIG. 8 is a sectional view showing a state that deposits adhere to a conventional susceptor.

### DETAILED DESCRIPTION OF THE PREFERRED EMBODIMENT

Referring now to the accompanying drawings, the preferred embodiments of the present invention will be described below.

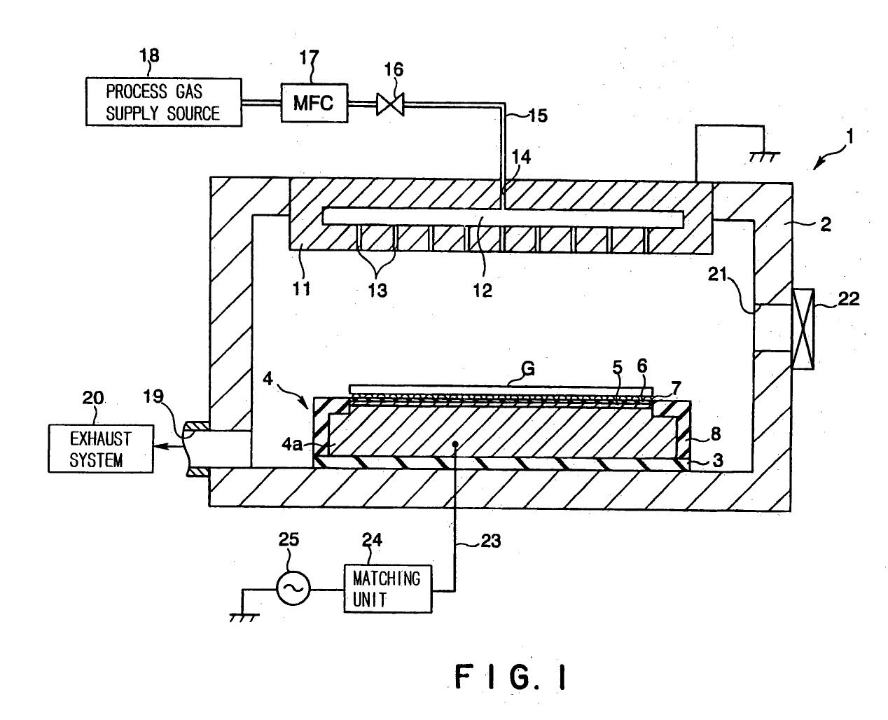

FIG. 1 is a sectional view showing a preferred embodiment of a plasma etching system in which a susceptor serving as a substrate supporting table according to the present invention is provided. As shown in FIGS. 1 and 3, a susceptor 4 has a base 4a, a dielectric film 6 provided on the base 4a, and a plurality of protrusions 7 formed on the dielectric film 6.

The protrusions 7 are uniformly distributed in a substrate-supporting region on the dielectric film 6, and a substrate G is supported on the protrusions 7. The protrusions 7 serve as spacers for isolating the susceptor 4 from the substrate G. Thus, it is possible to prevent the substrate G from being adversely influenced by the deposits adhering to the susceptor 4.

Each of the protrusions 7 preferably has a height of from 50 to 100 μm inclusive. It is possible to sufficiently prevent the deposits from having a bad influence on the substrate G if the height of each of the protrusions 7 is 50 μm or more, in view of the amount of the deposits adhering to the susceptor 4. On the other hand, if the height exceeds 100 μm, there are problems in that the strength of the protrusions 7 decreases and that the etching rate of the substrate G decreases, and there is a disadvantage in that the time required to form the protrusions 7 by the thermal spraying increases as will be described later. The diameter of each of the protrusions 7 is preferably in the range of from 0.5 mm to 1 mm. The distance between adjacent protrusions 7 is preferably in the range of from 0.5 mm to 30 mm, more preferably in the range of from 5 mm to 10 mm. The arrangement pattern of the protrusions 7 should not be particularly limited, and may be, e.g., a staggered arrangement.

At least the top portion of each of the protrusions 7 is preferably formed so as to have a curved surface, such as a semi-spherical surface, so that the top thereof point-contacts the substrate G. Thus, it is very difficult for deposits to adhere to the contact portions of the protrusions 7 to the substrate G. On the other hand, if each of the protrusions 7 is cylindrical or prismatic, there is a disadvantage in that deposits are easy to adhere to the top face of each of the protrusions 7 since the top face is a flat face.

The protrusions 7 are formed of a ceramic which is generally known as a material having high durability and high corrosion resistance. The ceramic forming the protrusions 7 should not be particularly limited. Typical examples of the ceramics include insulating materials, such as Al₂O₃, Zr₂O₃ and Si₃N₄. However, the ceramic may be a material having a conductivity to some extent, such as SiC. The protrusions 7 are formed by the thermal spraying.

The dielectric film 6 may be formed of any one of dielectric materials which include high insulating materials as well as conductive materials in such an extent that the movement of electric charges are permitted. Such a dielectric film 6 is preferably formed of a ceramic in view of durability and corrosion resistance. In this case, the ceramic should not be particularly limited. Similar to the protrusions 7, typical examples of the ceramics include insulating materials, such as Al₂O₃, Zr₂O₃ and Si₃N₄, and may include a material having a conductivity to some extent, such as SiC. Such a dielectric film 6 may be formed by the thermal spraying. After the thermal spraying, the surface of the dielectric film 6 may be smoothed by polishing or the like.

The base 4a is designed to support thereon the dielectric film 6, and is formed of a conductive material, e.g., a metal, such as aluminum, or carbon.

A method for forming the protrusions 7 on the dielectric film 6 by the thermal spraying will be described below.

It is considered that the protrusions 7 are formed by another method, such as machining or etching. However, in that case, there are problems on technique and costs. Therefore, in this preferred embodiment, the following method is adopted.

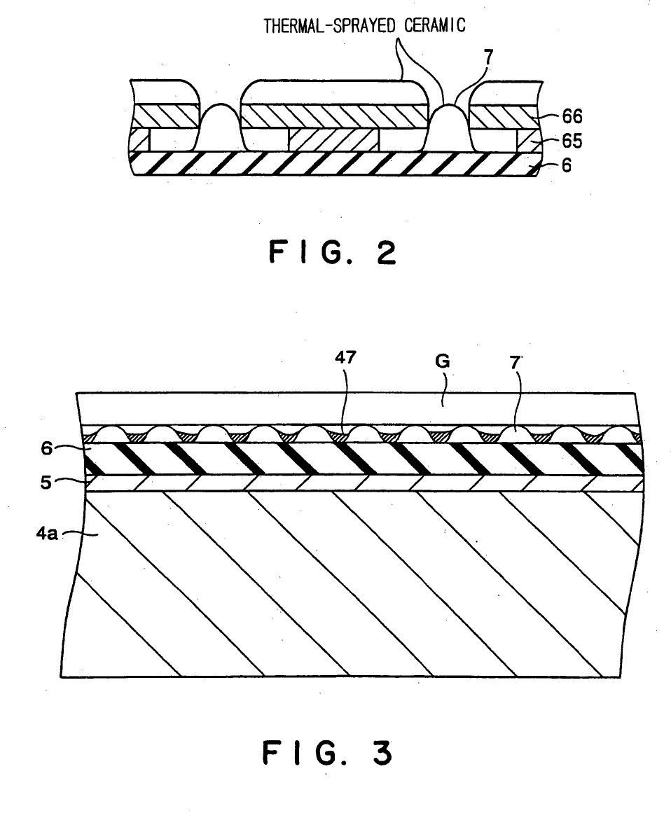

As shown in FIG. 2, an aperture plate 66 having a plurality of circular apertures is held on the dielectric film 6 without contact, i.e. in a position apart therefrom. In order to achieve this, a spacer member 65 is mounted on the dielectric film 6, and the aperture plate 66 is mounted thereon. That is, the spacer member 65 is arranged between the aperture plate 66 and the dielectric film 6. The spacer member 65 is preferably formed of a metal or a heat resistant resin. The spacer member 65 is preferably formed of a heat resistant resin sheet with adhesive since it can be directly bonded to the dielectric film 6. The spacer member 65 has a smaller top projected area than that of the aperture plate 66 (except for apertures), and has such a shape that the periphery of the spacer member 65 is arranged outside of the periphery of each of apertures of the aperture plate 66. The base material of the aperture plate 66 is, e.g., a metal plate, specifically a stainless plate, having a thickness of about 0.3 mm.

The above described ceramic is thermal-sprayed via the aperture plate 66 to form the protrusions 7 on portions of the dielectric film 6 facing the apertures. Thus, the protrusions 7 can be relatively easily formed. By thus thermal-spraying via the aperture plate 66 serving as a mask having a plurality of apertures, the top portion of each of the protrusions 7 can have a curved surface. It is considered that the reason for this is that the peripheral portions of the apertures serve as barriers during the thermal spraying to prevent the ceramic from dispersing to the outside in radial directions.

Thus, the protrusions 7 formed by the thermal spraying can be controlled so as to have a desired shape. After the thermal spraying, the aperture plate 66 and the spacer member 65 are removed.

There are some cases where gas holes are formed when the protrusions 7 are formed by thermal-spraying the ceramic. In such cases, sealing process is carried out after forming the protrusions 7. This is the same when the dielectric film 6 is formed by the thermal spraying.

If the material of the dielectric film 6 is the same as the material of the protrusions 7, both are strongly bonded to each other to be preferred. However, if the bonding of both is sufficient in the temperature range during processing the substrate, the materials of both may be different. If the materials of the protrusions 7 and dielectric film 6 are the same, these may be continuously formed by the thermal spraying.

As shown in FIG. 3, an intermediate layer 5 is provided between the base 4a and the dielectric film 6. The intermediate layer 5 is made of a material having an intermediate thermal expansion coefficient between the base 4a and the dielectric film 6, and has the function of relieving the difference in thermal expansion between the base 4a and the dielectric film 6. The intermediate layer 5 may be provided in order to strengthen the bonding of the base 4a to the dielectric film 6. The intermediate layer 5 is not essential, and the intermediate layer 5 may be omitted when the size of the susceptor 4 is small, when the variation in temperature is small or when the bonding of the base 4a to the dielectric film 6 is strong. The number of the intermediate layers 5 should not be limited to one, and may be two or more.

When the base 4a is made of aluminum and when the dielectric film 6 is made of a ceramic, the intermediate layer 5 may be made of, e.g., an alloy of nickel and aluminum. The method for forming the intermediate layer 5 should not be limited.

In the processing system shown in FIG. 1, deposits 47, such as materials etched from the substrate G, accumulate on the surface of the dielectric film 6 of the susceptor 4 as shown in FIG. 3 by repeating an etching processing. However, in this preferred embodiment, the protrusions 7 serve as spacers between the dielectric film 6 and the substrate G, so that it is difficult for the deposits accumulating on the susceptor 4 to contact the substrate G. Thus, it is possible to prevent the susceptor 4 from contacting the substrate G via the deposits 47 so as to eliminate the disadvantages in that etching irregularity is caused and that the substrate G is stuck onto the susceptor 4.

Referring to FIG. 1, a processing system using the susceptor 4 with the above described construction according to the present invention will be described below.

This processing system 1 is shown by a sectional view as an example of a system for carrying out a predetermined processing for an LCD glass substrate, and as an example of a capacitive coupled parallel-plate plasma etching system. However, the processing system according to the present invention should not be limited to the plasma etching system.

The plasma etching system 1 has a prismatic-cylindrical processing vessel 2 of, e.g., aluminum, the surface of which is alumite-processed (anodized). On the bottom of the processing vessel 2, a prismatic insulating plate 3 of an insulating material is provided. On the insulating plate 3, the above described susceptor 4 for supporting thereon an LCD glass substrate G serving as a substrate to be processed is provided. An insulating member 8 is provided so as to surround the periphery of the base 4a of the susceptor 4 and the peripheral portion of the top face (a portion in which the intermediate layer 5 and the dielectric film 6 are not provided) of the base 4a.

The susceptor 4 is connected to a feeder 23 for feeding a high-frequency power. The feeder 23 is connected to a matching unit 24 and a high-frequency power supply 25. From the high-frequency power supply 25, a high-frequency power of, e.g., 13.56 MHz, is supplied to the susceptor 4.

Above the susceptor 4, a shower head 11 serving as a top electrode is provided parallel to the susceptor 4. The shower head 11 is supported on the top of the processing vessel 2. The shower head 11 defines therein a space 12, and has a plurality of discharge holes 13 for discharging a process gas in its wall facing the susceptor 4. The shower head 11 is grounded, and is associated with the susceptor 4 for constituting a pair of parallel plate electrodes.

In the top face of the shower head 11, a gas inlet 14 is formed. The gas inlet 14 is connected to a process gas supply pipe 15. The process gas supply pipe 15 is connected to a process gas supply source 18 via a valve 16 and a mass flow controller 17. From the process gas supply source 18, a process gas for etching is supplied. As the process gas, a gas usually used in this field, such as a halogen gas, O₂ gas or Ar gas, can be used.

To the bottom portion of the side wall of the processing vessel 2, an exhaust pipe 19 is connected. The exhaust pipe 19 is connected to an exhaust system 20. The exhaust system 20 has a vacuum pump, such as a turbo-molecular pump, so as to be capable of evacuating the processing vessel 2 to a predetermined reduced pressure atmosphere. The side wall of the processing vessel 2 is provided with a substrate transfer port 21, and a gate valve 22 for opening and closing the substrate transfer port 21. While the gate valve 22 is open, the substrate G is transferred between the processing vessel 2 and a load-lock chamber (not shown) adjacent thereto.

The processing operation of the plasma etching system 1 with this construction will be described below.

First, after the gate valve 22 is open, the substrate G serving as the substrate to be processed is carried in the processing vessel 2 from the load-lock chamber (not shown) via the substrate transfer port 21. The carried-in substrate G is mounted on the protrusions 7 formed on the susceptor 4. In this case, the delivery of the substrate G is carried out by means of a lifter pin (not shown) provided so as to be capable of passing through the susceptor 4 to project upwards. Thereafter, the gate valve 22 is closed, and the processing vessel 2 is evacuated by the exhaust system 20 to a predetermined degree of vacuum.

Thereafter, the valve 16 is open, the process gas passes through the process gas supply pipe 15 and the gas inlet 14 to be fed to the interior space 12 of the shower head 11 while the flow rate of the process gas is controlled by the mass flow controller 17. This process gas pass through the discharge holes 13 to be uniformly discharged onto the substrate G, and the pressure in the processing vessel 2 is maintained at a predetermined value.

In this state, a high-frequency power is applied to the susceptor 4 from the high-frequency power supply 25 via the matching unit 24. Thus, a high-frequency field is produced between the susceptor 4 serving as the bottom electrode and the shower head 11 serving as the top electrode. By this field, the process gas is dissociated to be plasma, so that the substrate G is etched.

After the etching is thus carried out, the application of the high-frequency power from the high-frequency power supply 25 is stopped. Thereafter, the pressure in the processing vessel 2 is raised to a predetermined pressure, and the gate valve 22 is opened. Then, the substrate G is carried out of the processing vessel 2 to the above described load-lock chamber via the substrate transfer port 21, so that the etching of the substrate G is completed.

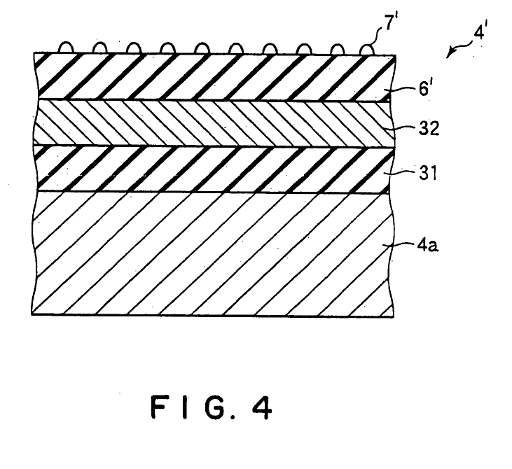

The susceptor (substrate supporting table) in this preferred embodiment may be provided with an electrostatic chuck. In that case, as shown in FIG. 4, a first dielectric film 31, a conductive layer 32 serving as an electrostatic electrode layer, a second dielectric film 6′ and protrusions 7′ may be sequentially stacked on the base 4a to constitute a susceptor 4′.

The method for forming the first dielectric film 31, the conductive layer 32 and the second dielectric film 6′ constituting the electrostatic chuck should not be limited, and all of them may be formed by the thermal spraying. Part or all of the layers may be smoothed by polishing or the like.

The protrusions 7′ are formed of the same ceramic as that of the above described protrusions 7. The materials of the first dielectric film 31 and second dielectric film 6′ should not be limited if they are formed of the same dielectric material as that of the above described dielectric film. The material of the first dielectric film 31 may be the same as that of the second dielectric film 6′. One or more intermediate layers may be provided between the base 4a and the first dielectric film 31 and between the second dielectric film 6′ and the protrusions 7′. The function of these intermediate layers is the same as that of the above described intermediate layer 5. On the second dielectric film 6′, one or more coating layers may be formed.

The protrusions 7′ are uniformly distributed in a region of the second dielectric film 6′ above which the substrate G is supported. The susceptor 4′ is designed to hold the substrate G on the protrusions 7′ thereof. The shapes and forming methods of the second dielectric film 6′ and protrusions 7′ are the same as the above described shapes and forming methods with respect to the dielectric film 6 and the protrusions 7. The base 4a of the susceptor 4 shown in FIG. 1 can be formed as an electrostatic electrode to function as the electrostatic chuck without forming the above described construction.

On such a susceptor, the substrate G is held on the electrostatic chuck and temperature-controlled to carry out a processing, e.g., etching, for the substrate G. Then, by repeating the etching for a plurality of substrates G, deposits accumulate on the surface of the dielectric film 6 formed on the electrostatic chuck. However, it is difficult for the deposits to contact the substrate G since the protrusions 7′ also serve as spacers between the substrate G and the dielectric film 6 in this preferred embodiment. Therefore, it is possible to prevent the susceptor 4 from contacting the substrate G via the deposits 47 so as to eliminate the disadvantages in that etching irregularity is caused and that the substrate G is fixed to the susceptor 4 after the electrostatic holding by the electrostatic chuck is turned off.

Other preferred embodiments of the present invention will be described below.

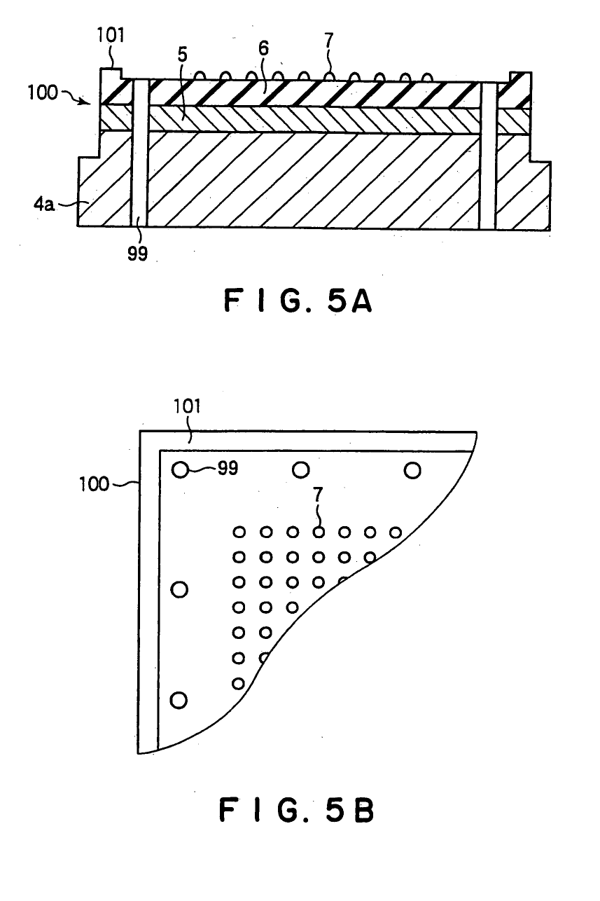

A susceptor 100 shown in FIGS. 5A and 5B has a plurality of heat transfer fluid passages 99 passing through a base 4a, an intermediate layer 5 and a dielectric film 6 in directions substantially perpendicular thereto and being open as outlets in the peripheral portion on the surface of the dielectric film 6. Through these passages 99, spaces formed between a substrate G and the susceptor 100 by protrusions 7 can be filled with heat transfer fluid, e.g., helium gas, so that the substrate can be uniformly cooled. Thus, the temperature of the substrate can be uniform, and the plasma processing, such as etching, can be uniformly carried out over the whole surface of the substrate. A stepped portion 101 is provided on the susceptor 100. The stepped portion 101 surrounds outside the outlets of the respective passages 99 and rising from other portions of the susceptor 100. By this stepped portion 101, it is possible to inhibit the heat transfer fluid from diffusing to a region outside of the susceptor 100. The height of the top face of the stepped portion 101 is set to be the height of the protrusions 7 or more.

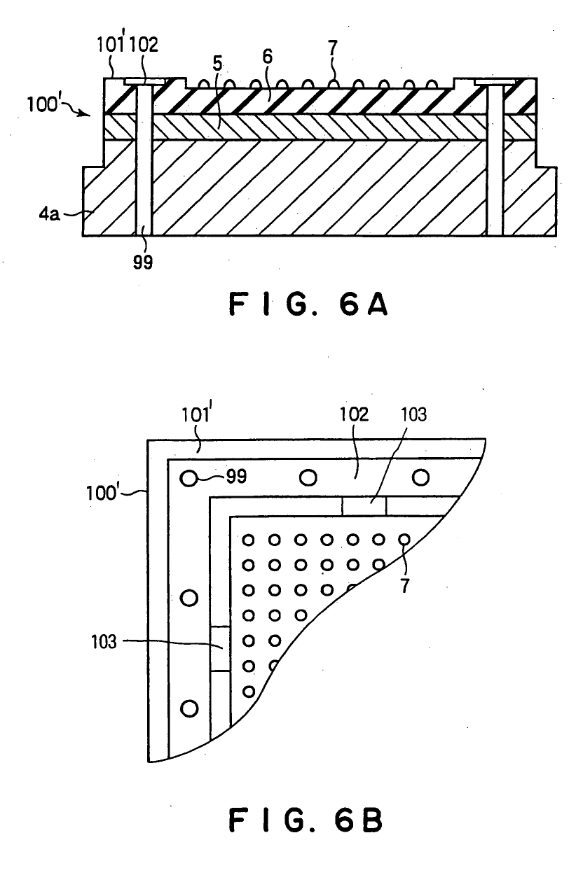

A susceptor 100′ shown in FIGS. 6A and 6B has a wider stepped portion 101′ than the above described stepped portion 101, and is provided with a groove 102 extending along the center line of the top face of the stepped portion 101′. In this case, the outlets of heat transfer fluid passages 99 are open to the bottom face of the groove 102. Cut-out portions 103 are suitably formed for allowing the inside of the stepped portion 101′ to be communicated with the inside of the groove 102. Also with this construction, it is possible to inhibit the heat transfer fluid from diffusing a region other than the susceptor.

Also in the susceptors shown in FIGS. 5A through 6B, an electrostatic chuck may be provided as described above.

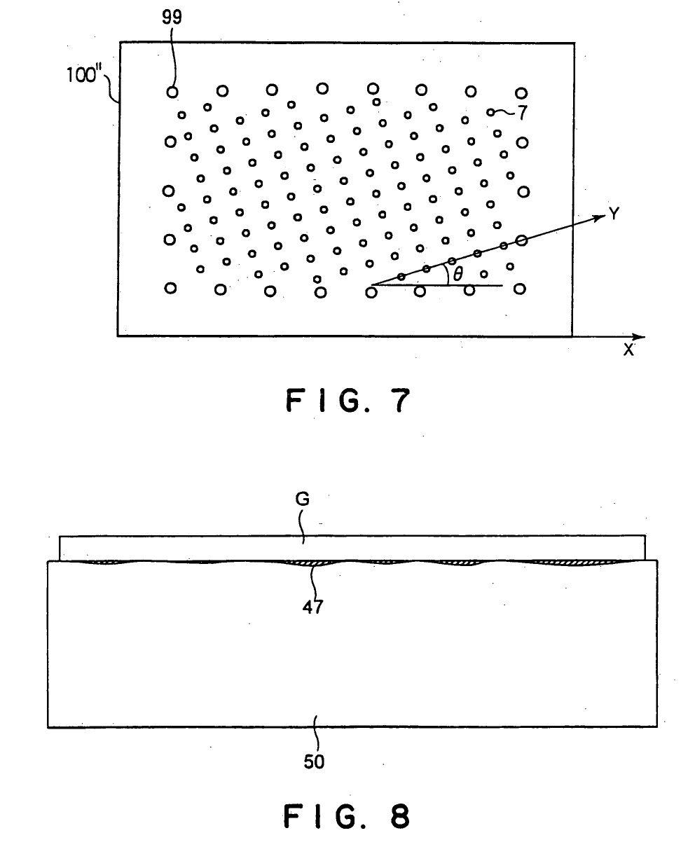

A susceptor 100″ shown in FIG. 7 has a rectangular plane shape, and a plurality of protrusions 7 arranged so as to form an orthogonal lattice. An angle θ between one axis Y of the orthogonal lattice and one side X of the susceptor 100″ is set to be from more than 0° to not more than 45°. The orthogonal lattice herein means a lattice having a rectangular unit lattice (basic lattice).

A semiconductor circuit pattern is exposed to light on a rectangular substrate, such as a glass substrate, and the semiconductor circuit pattern or the like is developed by etching. In this semiconductor circuit pattern or the like, source lines, gate lines and others are arranged in parallel to the respective sides of the rectangular substrate. If a certain protrusion of the susceptor overlaps with a specific circuit pattern, there is the possibility that an abnormal contact may be caused in the overlapping portion to vary heat conduction and electric field thereof to cause etching irregularity. The arrangement of protrusions in this susceptor 100″ is designed to inhibit the occurrence of such etching irregularity. From the standpoint of the inhibition of etching irregularity, the protrusions 7 may be irregularly arranged, not in the form of the orthogonal lattice. In such a susceptor for inhibiting etching irregularity, the constructions shown in FIGS. 5A through 6B may be adopted.

The processing system with the susceptor having the heat transfer fluid passages 99 shown in FIGS. 5 through 7 is the same as the processing shown in FIG. 1, except that the heat transfer fluid passages 99 are connected to a heat transfer fluid source, such as a helium source.

The present invention should not be limited to the above described preferred embodiments. For example, while the plasma etching system has been described as an example of a processing system according to the present invention, the present invention should not be limited thereto, but the invention may be applied to another plasma processing system, such as an ashing or CVD deposition system. While the RIE type capacitive coupled system for applying the high-frequency power to the bottom electrode has been described as an example, the present invention may be applied to a system of a type for supplying a high-frequency power to a top electrode. The present invention should not be limited to the capacitive coupled system, but the invention may be applied to an inductive coupled system. The substrate to be processed should not be limited to the LCD glass substrate, but it may be a semiconductor wafer.

1. A method for producing a substrate supporting table, said method comprising the steps of:
forming a dielectric film on a base; and
forming a plurality of protrusions of ceramic on said dielectric film by thermal-spraying the ceramic onto said dielectric film via an aperture plate having a plurality of apertures.

2. A method as set forth in claim 1, further comprising a step of forming at least one intermediate layer between said base and said dielectric film.

3. A method as set forth in claim 1, wherein said step of forming said protrusions is carried out with said aperture plate held in a position apart from said dielectric film.

4. A method as set forth in claim 3, wherein said aperture plate is held in said position apart from said dielectric film by inserting a spacer member between said aperture plate and said dielectric film, said spacer member corresponding to the outside of peripheries of said apertures of said aperture plate.

5. A method for producing a substrate supporting table, said method comprising the steps of:
forming a first dielectric film on a base;
forming a conductive layer on said first dielectric film;
forming a second dielectric film on said conductive layer; and
forming a plurality of protrusions of ceramic on said second dielectric film by thermal-spraying the ceramic onto said second dielectric film via an aperture plate having a plurality of apertures.

6. A method as set forth in claim 5, further comprising a step of forming at least one intermediate layer between said base and said first dielectric film.

7. A method as set forth in claim 5, wherein said step of forming said protrusions is carried out with said aperture plate held in a position apart from said second dielectric film.

8. A method as set forth in claim 7, wherein said aperture plate is held in said position apart from said second dielectric film by inserting a spacer member between said aperture plate and said second dielectric film, said spacer member corresponding to the outside of peripheries of said apertures of said aperture plate.

9. A method as set forth in claim 5, further comprising a step of forming at least one coating layer on said second dielectric film before said step of forming said protrusions.

10-29. (canceled)
